(19) United States
(12) Patent Application Publication
(10) Pub. No.: US 2013/0028291 A1
(43) Pub. Date: Jan. 31, 2013

(54) TEMPERATURE MEASUREMENT SYSTEM AND MANUFACTURING METHOD OF SAME

(71) Applicants: Masayuki TOBO, Kawasaki-Shi (JP); Mamoru Fukui, Yokohama-Shi (JP); Kazuhisa Watanabe, Sagamihara-Shi (JP); Hisanari Yoshida, Musashino-Shi (JP); Shigeru Yamaji, Yokohama-Shi (JP); Makoto Suto, Zama-Shi (JP)

(72) Inventors: Masayuki TOBO, Kawasaki-Shi (JP); Mamoru Fukui, Yokohama-Shi (JP); Kazuhisa Watanabe, Sagamihara-Shi (JP); Hisanari Yoshida, Musashino-Shi (JP); Shigeru Yamaji, Yokohama-Shi (JP); Makoto Suto, Zama-Shi (JP)

(73) Assignees: Toshiba Plant Systems & Services Corporation, Yokohama-Shi (JP); Kabushiki Kaisha Toshiba, Tokyo (JP)

(21) Appl. No.: 13/543,290

(22) Filed: Jul. 6, 2012

(30) Foreign Application Priority Data
Jul. 25, 2011 (JP) 2011-162240

(51) Int. Cl. G01K 7/02; G01R 3/00

(52) U.S. Cl. 374/179; 29/595; 374/E07.004

(57) ABSTRACT

According to one embodiment, a temperature measurement system including: a plurality of thermocouples; a transmission signal conversion unit configured to convert, to a transmission signal, the thermo-electromotive force generated by each of the plurality of the thermocouple and configured to output the transmission signal; a plurality of transmission units configured to transmit the transmission signal outputted from the transmission signal conversion unit; a first connection unit configured to connect between each of the plurality of the transmission units; a second connection unit configured to connect at least one of the plurality of transmission units to a processing unit configured to process the transmission signal; and a housing unit configured to house at least the first connection unit.

### CROSS-REFERENCE TO RELATED APPLICATION

This application is based upon and claims the benefit of priority from Japanese Patent Application No. 2011-162240, filed Jul. 25, 2011; the entire contents of which are incorporated herein by reference.

### FIELD

Embodiments of the present invention relate to a temperature measurement system of an industrial plant such as a thermal power generation plant, a nuclear power generation plant, a chemical plant, and various factories, and a manufacturing method of the temperature measurement system.

### BACKGROUND

Various instrument sensors (instruments and sensors) are installed in an industrial plant for the purpose of monitoring and controlling the industrial plant. Cables are installed between the instrument sensors and a monitoring and control apparatus which monitors the measurement values measured by the instrument sensors. Current signals and voltage signals are transmitted by the cables.

As the process amounts monitored and controlled in the industrial plant, there are mainly pressure, flow rate, and temperature. Among these amounts, a transmitter is used for the measurement of pressure and flow rate. A thermocouple is used for the measurement of temperature.

The thermocouple is attached in a measurement area in the industrial plant. The measurement area is an area (hereinafter referred to as “apparatus installation site area”) in the industrial plant, in which area facility apparatuses, such as a pump, a fan, a turbine, and a valve, and pipes are arranged. The apparatus installation site area is also an area in the industrial plant, in which area main facility apparatuses are particularly intensively arranged.

Generally, the distance from the measurement area (apparatus installation site area) to the monitoring and control apparatus is about 200 m to 400 m. When a thermocouple is used to provide a connection over this length, a very long thermocouple is required. This results in high cost, and hence such connection is not realistic.

In order to reduce the installation cost and to shorten the installation period, an on-site transmission technique for converting, into a transmission signal, a thermo-electromotive force signal generated by a thermocouple and for transmitting the transmission signal has been put into practical use. With the on-site transmission technique practically using the recent information technology (IT), and the like, the amount of cables can be significantly reduced and rationalized.

### BRIEF DESCRIPTION OF THE DRAWINGS

In the accompanying drawings:

FIG. 1 is a view showing a configuration of a first embodiment of a temperature measurement system according to the present invention;

FIG. 2 is a view showing a temperature measurement system as a comparison example of the temperature measurement system according to the first embodiment;

FIG. 3 is a view showing a measurement system as a reference example of the temperature measurement system according to the first embodiment;

FIG. 4 is a view showing a modification of the temperature measurement system according to the first embodiment;

FIG. 5 is a view showing a configuration of a second embodiment of a temperature measurement system according to the present invention; and

FIG. 6 is a view showing a configuration of a third embodiment of a temperature measurement system according to the present invention.

### DETAILED DESCRIPTION

Embodiments of a temperature measurement system according to the present invention and a manufacturing method of the temperature measurement system will be described with reference to the accompanying drawings.

The industrial plants have “apparatus installation site area”. The apparatus installation site area is an area in which facility apparatuses, such as a pump, a fan, a turbine, and a valve, and pipes are arranged. The apparatus installation site area is most intensively arranged main facility apparatuses and pipes. Therefore, there is a possibility of leakage of hot water, steam and gas generated in the apparatus installation site area.

When applying an on-site transmission technique to the industrial plants, a transmission cable is installed in the apparatus installation site area in the industrial plants. The transmission cables may be physically weak, and hence need to be protected from the surrounding environment of the apparatus installation site area.

Further, measures need to be taken so that the transmission cables do not obstruct the human activities for maintenance and patrol inspection. The transmission cables need to be protected from the surrounding environment including the human activities, and also need to be arranged so as not to obstruct the human activities. The human activities are obstructed in such cases where the cables interfere with the path to access a facility apparatus, and where, when a facility apparatus is disassembled for maintenance, the cables are brought into contact with the disassembled facility apparatus.

The embodiments of a temperature measurement system according to the present invention and a manufacturing method of the temperature measurement system have been made in view of the above described circumstances. An object of the embodiments is to provide a temperature measurement system and a manufacturing method of the temperature measurement system to which an on-site transmission technique is applied and which can improve the reliability thereof.

This and other objects can be achieved according to the present invention by providing temperature measurement system, including: a temperature measurement system including: a plurality of thermocouples; a transmission signal conversion unit configured to convert, to a transmission signal, the thermo-electromotive force generated by each of the plurality of the thermocouple and configured to output the transmission signal; a plurality of transmission units configured to transmit the transmission signal outputted from the transmission signal conversion unit; a first connection unit configured to connect between each of the plurality of the transmission units; a second connection unit configured to connect at least one of the plurality of transmission units to a processing unit configured to process the transmission signal; and a housing unit configured to house at least the first connection unit.

### First Embodiment

A first embodiment of a temperature measurement system according to the present invention and a manufacturing method of the temperature measurement system will be described with reference to the accompanying drawings.

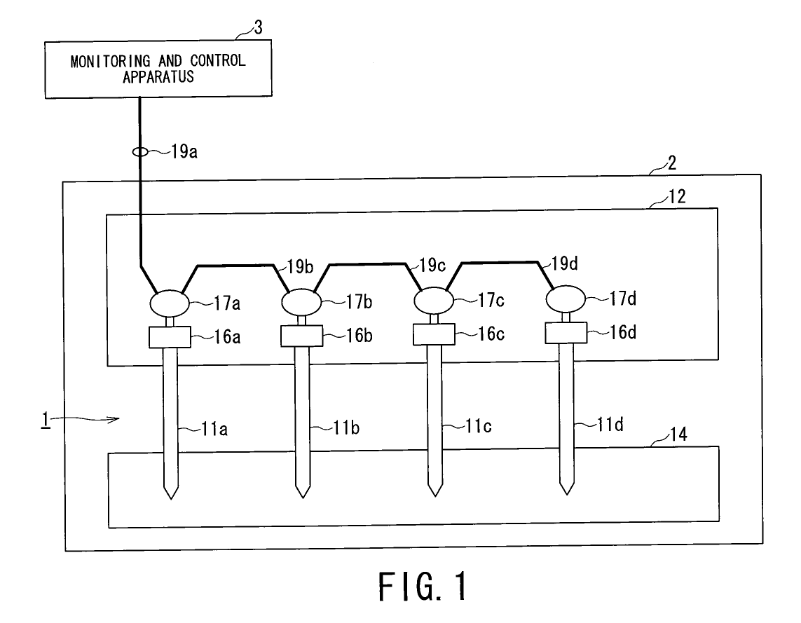

FIG. 1 is a view showing a configuration of a first embodiment of a temperature measurement system according to the present invention.

The temperature measurement system 1 according to the first embodiment is provided in an industrial plant, such as a thermal power generation plant, a nuclear power generation plant, a chemical plant, and various factories.

The temperature measurement system 1 is mainly provided in an industrial plant 2, and is connected, by a transmission cable 19a, to a monitoring and control apparatus 3 provided outside the industrial plant 2.

The monitoring and control apparatus 3 monitors measurement values on the basis of transmission signals measured by thermocouples 11a to 11d and transmitted by the on-site transmission. The monitoring and control apparatus 3 includes an input apparatus which is a hardware portion for receiving the transmission signals (measurement signals). The input apparatus may be separated as a remote I/O apparatus so as to be installed at a place which is closer to the temperature measurement system 1 and is inside or outside the industrial plant 2. In this case, cables are installed between the remote I/O apparatus and the thermocouples 11a to 11d and between the remote I/O apparatus and the monitoring and the control apparatus 3.

For example, 200 to 300 of thermocouples 11a to 11d are provided in the industrial plant 2 (for example, when 500 instrument sensors are provided as a whole). In the first embodiment, four thermocouples 11a to 11d are illustrated for convenience of description. Each of the thermocouples 11a to 11d is provided in a measurement area 14 that is an apparatus installation site area.

The measurement area 14 is an area in the industrial plant 2, in which area facility apparatuses, such as a pump, a fan, a turbine, and a valve, and pipes are arranged. The measurement area 14 is also an area in the industrial plant 2, in which area main facility apparatuses are particularly intensively arranged. Note that the measurement area 14 is not clearly separated or isolated from the other area, and a part of the facility apparatuses, and the like, are also installed in the other area.

Each of the thermocouples 11a to 11d has, at the tip portion thereof, a hot junction as a measurement place, and also has a cold junction (head portion) at the end portion opposite to the measurement place. The thermocouples 11a to 11d respectively include, at the cold junctions thereof, A/D converters 16a to 16d, and adapters 17a to 17d in this order.

The A/D converters 16a to 16d (transmission signal conversion units) respectively A/D-convert the thermo-electromotive forces generated by the thermocouples 11a to 11d into transmission signals, so as to output the transmission signals. The adapters 17a to 17d (transmission units) transmit the transmission signals transmitted from the A/D converters 16a to 16d to the transmission cables 19a to 19d, respectively.

Note that an apparatus configured by integrating each of the A/D converters 16a to 16d and each of the adapters 17a to 17d may be incorporated in the cold junction, or the like, of each of the thermocouples 11a to 11d. The transmission signals may be transmitted to the monitoring and control apparatus 3 via a relay apparatus provided between the monitoring and control apparatus 3 and the adapters 17a to 17d.

The transmission cables 19a to 19d are, for example, optical cables, and transmit, to the monitoring and control apparatus 3, the transmission signals transmitted from the adapters 17a to 17d, respectively.

The transmission cable 19a (second connection unit) connects the adapter 17a to the monitoring and control apparatus 3. The transmission cable 19b (first connection unit) connects the adapter 17a to the adapter 17b. The transmission cable 19c (first connection unit) connects the adapter 17b to the adapter 17c. The transmission cable 19d (first connection unit) connects the adapter 17c to the adapter 17d.

The transmission cables 19a to 19d are connected by a wiring system (so-called Daisy Chain system) in which the mutually adjacent adapters 17a to 17d are connected in series. The transmission signal transmitted from each of the adapters 17b to 17d are successively transmitted through the required transmission cables 19b to 19d, so as to be transmitted to the adapter 17a. Eventually, the respective transmission signals are transmitted to the monitoring and control apparatus 3 through the transmission cable 19a.

In the Daisy Chain system, only one cable of the transmission cable 19a is used as the transmission cable which is installed over a long distance (generally, a length of 200 to 400 m) so as to be connected to the monitoring and control apparatus 3. The transmission cables 19b to 19d other than the transmission cable 19a need only to be capable of connecting between mutually adjacent adapters 17a to 17d, and hence need only to have a very short length (generally, about 10 m to 20 m).

Even in the case where the number of thermocouples 11a to 11d is increased, it is only necessary that the transmission cables 19b to 19d having short lengths are installed between the adapters adjacent to each other. Thus, from the viewpoint of reducing the amount of cable, the Daisy Chain system is advantageous.

Note that any of one-core cable or two-core cable may also be used as the transmission cables 19a to 19d. When two-core cables are applied, the transmission cables 19a to 19d can also perform power supply from the monitoring and control apparatus 3 to the A/D converters 16a to 16d and the adapters 17a to 17d, in addition to the transmission of the transmission signals. Each of the transmission cables 19a to 19d is configured as a single cable in which one core for supplying a positive voltage and the other core for supplying a negative voltage are paired so as to satisfy the predetermined functions.

A housing 12 (housing unit) is a housing which is made of, for example, iron or FRP (Fiber Reinforced Plastic) and has a self-closing property. In such a case where the housing 12 is installed at a high place, it is preferred that the housing 12 is made of FRP so as to be lightened in weight. The housing 12 has a size corresponding to the number of the thermocouples housed in the housing 12.

The housing 12 houses the transmission cables 19a to 19d (a part of the transmission cables 19a), the A/D converters 16a to 16d, the adapters 17a to 17d, the cold junctions at which the thermocouples 11a to 11d are respectively connected to the A/D converters 16a to 16d.

The transmission cables 19a and the thermocouples 11a to 11d are provided so as to pass through the housing 12. The housing 12 has required protective properties which can sufficiently protect the apparatuses installed in the housing 12 in particular from hot water, steam and gas generated in the surrounding environment of the apparatus installation site area as the measurement area 14, and from the human activities.

Note that the housing 12 is provided to protect the transmission cables 19a to 19d from the surrounding environment and hence is required only to house at least the transmission cables 19a to 19d.

It is preferred that the housing 12 is installed in a suitable place which is free from the influence of human activities, and the like, and is also separated, by a required distance, from the apparatus installation site area as the measurement area 14, and in which the connection to the cold junctions of the thermocouples 11a to 11d can be established.

Here, a temperature measurement system as a comparison example of the temperature measurement system 1 according to the first embodiment will be described.

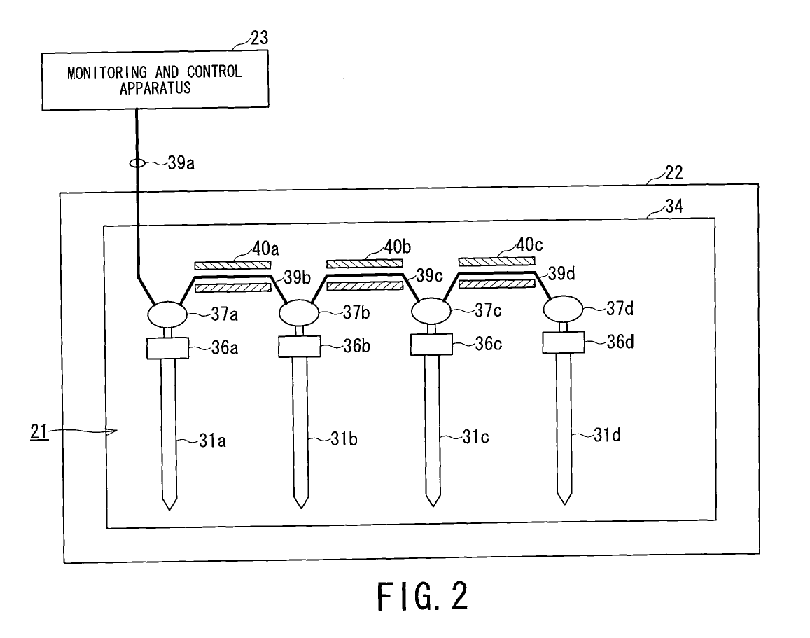

FIG. 2 is a view showing a temperature measurement system 21 as a comparison example of the temperature measurement system 1 according to the first embodiment.

The temperature measurement system 21 is mainly provided in an industrial plant 22 and is connected, by a transmission cable 39a, to a monitoring and control apparatus 23 provided outside the industrial plant 22.

The temperature measurement system 21 includes thermocouples 31a to 31d, A/D converters 36a to 36d, adapters 37a to 37d, and transmission cables 39a to 39d which are almost the same as the thermocouples 11a to 11d, the A/D converters 16a to 16d, the adapters 17a to 17d and the transmission cables 19a to 19d of the temperature measurement system 1 according to the first embodiment.

The temperature measurement system 21 is different from the temperature measurement system 1 according to the first embodiment in that the transmission cables 39a to 39d are not housed in the housing. Further, the thermocouples 31a to 31d, the A/D converters 36a to 36d, the adapters 37a to 37d, and the transmission cables 39a to 39d are installed in the apparatus installation site area as a measurement area 34.

The transmission cables 39a to 39d provided in the temperature measurement system 21 configured in this way need to be protected so as not to be damaged and disconnected due to the influence of the surrounding environment of the measurement area 34 as the apparatus installation site area in which facility apparatuses and pipes are most intensively arranged, and due to the influence of the human activities. Thus, the transmission cables 39a to 39d are protected by iron pipes 40a to 40c (so-called conduit pipes) as protective sheathes.

In the temperature measurement system 21, the extra conduit pipes 40a to 40c need to be provided, resulting in a cost increase corresponding to the material of the conduit pipes 40a to 40c. Further, while the arrangement relationships between the conduit pipes 40a to 40c and the facility apparatuses, and the like, are taken into consideration, the conduit pipes 40a to 40c are placed and installed in the measurement area 34 as the apparatus installation site area in which the facility apparatuses and the pipes are most intensively arranged. Thus, a large amount of design work and labor are required for the installation of the conduit pipes 40a to 40c.

Therefore, the temperature measurement system 21 as the comparison example has a disadvantage that the advantage of the rationalized cable arrangement based on the Daisy Chain system is reduced or canceled by the arrangement of the conduit pipes 40a to 40c.

Next, a measurement system 51, in which the on-site transmission is applied to transmitters for measuring pressure and flow rate, will be described as a reference example of the temperature measurement system 1 according to the first embodiment.

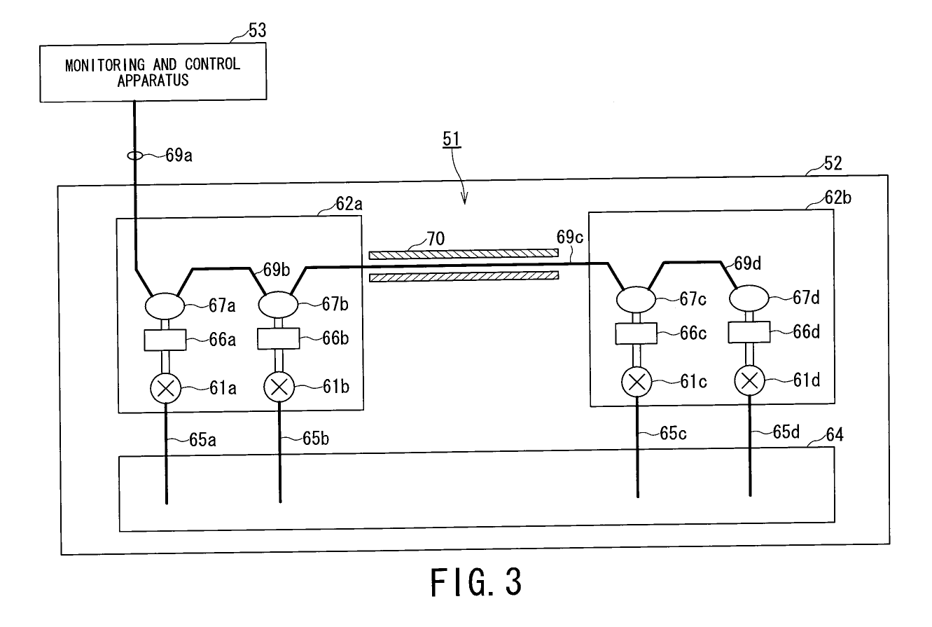

FIG. 3 is a view showing a measurement system 51 as a reference example of the temperature measurement system 1 according to the first embodiment.

The temperature measurement system 51 is mainly provided in an industrial plant 52, and is connected to a monitoring and control apparatus 53 provided outside the industrial plant 52 by a transmission cable 69a.

The measurement system 51 transmits signals obtained from transmitters 61a to 61d through transmission cables 69a to 69d connected by the Daisy Chain system. The configuration of the measurement system 51 is different from the configuration of the temperature measurement system 1 according to the first embodiment due to the difference in the measurement principle of the measurement sensors. That is, transmitters 61a to 61d are installed in the inside of local instrumentation panels 62a and 62b (or local instrumentation racks).

The transmitters 61a to 61d transmit physical pressure (of water, steam, oil, or the like) of the measurement object processes to the local instrumentation panels 62a and 62b via capillary tubes (instrumentation pipes) 65a to 65d. The transmitters 61a to 61d are respectively provided with A/D converters 66a to 66d and adapters 67a to 67d similarly to the thermocouples 11a to 11d. The adapters 67a to 67d transmit the transmission signals transmitted from the A/D converters 66a to 66d to the transmission cables 69a to 69d, respectively.

The local instrumentation panels 62a and 62b are installed in places away from the apparatus installation site area as a measurement area 64 in which the facility apparatuses are most intensively arranged. The local instrumentation panel 62a houses the transmitters 61a and 61b, the A/D converters 66a and 66b, the adapters 67a and 67b, and the transmission cables 65a to 69c. The local instrumentation panel 62b houses the transmitters 61c and 61d, the A/D converters 66c and 66d, the adapters 67c and 67d, and the transmission cables 69c and 69d.

The transmission cable 69c connects the adapter 67b in the local instrumentation panel 62a to the adapter 67c in the local instrumentation panel 62b. The transmission cable 69c is protected by a conduit pipe 70 similarly to the temperature measurement system 21 as the comparison example. In the inside of the local instrumentation panels 62a and 62b, the influence of hot water and steam, and the influence of maintenance/patrol personnel need not be taken into consideration, and hence the transmission cables 69b and 69d housed in the local instrumentation panels 62a and 62b need not be protected by the conduit pipe.

That is, the conduit pipe 70 is needed only for the transmission cable 69c which connects between the local instrumentation panels 62a and 62b, and hence the necessary number of the conduit pipes is comparatively small.

Here, the number of transmitters to which the Daisy Chain system can be applied is technically limited, and hence the method cannot be applied to the infinite number of transmitters. The maximum number of the transmitters connectable by the Daisy Chain system is limited by the transmission capacity of the one transmission cable 69a connected to the monitoring and control apparatus 53, and by constraints due to the other technical factors.

The maximum number of the transmitters is assumed to be 20 for the convenience of description. For example, when there are 20 transmitters, and when all of the 20 transmitters are housed in the same local instrumentation panel 62 (62a and 62b), all the transmission cables 69 (69a to 69d) are housed in the local instrumentation panel 62, and hence the conduit pipe 70 is not necessary at all. However, the length of the capillary tubes 65 (65a to 65d) is limited. Therefore, only the transmitters 61 (61a to 61d), which are installed at measurement places comparatively close to each other, can be housed in the one local instrumentation panel 62, and actually, only about at most five transmitters can be housed in the one local instrumentation panel 62.

Thus, when the Daisy Chain system is applied between the 20 transmitters, the 20 transmitters are separated into, for example, a set of 5 transmitters, a set of 4 transmitters, a set of 4 transmitters, a set of 3 transmitters, and a set of 4 transmitters, and then the sets of transmitters are housed in the five local instrumentation panels 62, respectively. Therefore, the conduit pipes 70 need to be installed to protect the four transmission cables 69 which connect between the local instrumentation panels 62.

On the other hand, the temperature measurement system 1 according to the first embodiment includes the housing 12 capable of housing the transmission cables 19a to 19d, without being influenced by the installation place and the number of the installed cables. Thereby, in the temperature measurement system 1, it is not necessary to provide the units for individually protecting the transmission cables 19a to 19d from the severe surrounding environment, and it is possible to fully utilize the merit of the on-site transmission in which the transmission signals are transmitted through the transmission cables 19a to 19d connected by the Daisy Chain system.

Further, in the industrial plant 2, the number of installed thermocouples 11 (11a to 11d), which provide indexes for measuring the performance of the plant, is larger than the number of the transmitters 61, and is a majority number (for example, 200 to 300) of the measurement sensors. When the temperature measurement system 1 is applied to the thermocouples 11, a great merit can be obtained from the viewpoint of rationalizing the arrangement of the cables.

Note that, in the temperature measurement system 1 according to the first embodiment, the measurement results of the respective thermocouples 11a to 11d are transmitted through the one transmission cable 19a, but the measurement results may also be transmitted through two or more transmission cables.

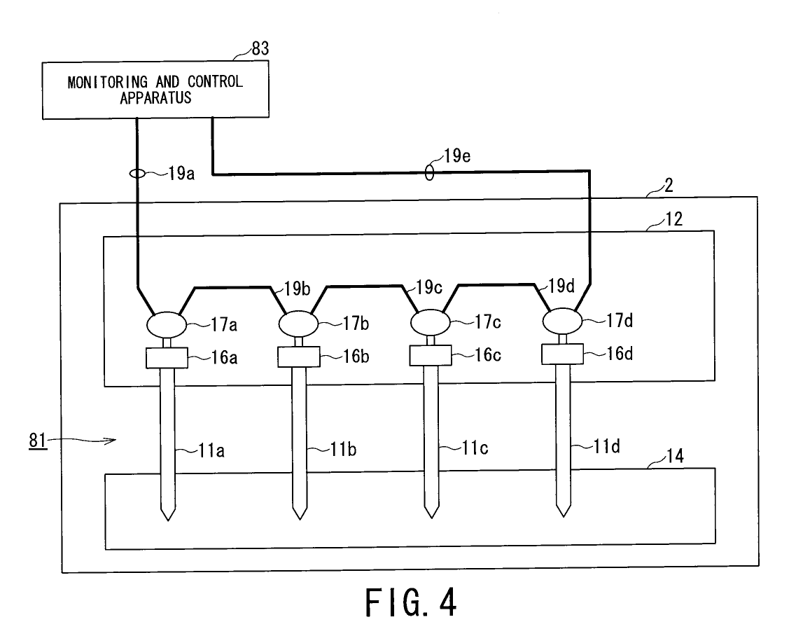

FIG. 4 is a view showing a modification of the temperature measurement system 1 according to the first embodiment.

In the temperature measurement system 81 as the modification, the configurations and portions corresponding to those of the temperature measurement system 1 according to the first embodiment are denoted by the same reference numerals and characters, and the description thereof is omitted.

In the temperature measurement system 81 as the modification, a transmission cable 19e (second connection unit) is newly provided between a monitoring and control apparatus 83 and the adapter 17d.

When the transmission cable 19b is disconnected in the case of the temperature measurement system 1 according to the first embodiment, the measurement results obtained from the thermocouples 11b to 11d other than the thermocouple 11a cannot be transmitted to the monitoring and control apparatus 3.

On the other hand, in the temperature measurement system 81 as the modification, the transmission cable 19e is provided, and thereby the measurement results of the thermocouples 11a to 11d can be surely transmitted to the monitoring and control apparatus 83.

That is, for example, even when the transmission cable 19b is disconnected, the measurement result of the thermocouple 11a can be transmitted to the monitoring and control apparatus 83 via the transmission cable 19a, and the measurement results of the thermocouples 11b to 11d can be respectively transmitted to the monitoring and control apparatus 83 via the required transmission cables 19c to 19e.

In the case where the Daisy Chain system is adopted for, connection of the transmission cables in the temperature measurement system 81, it is possible to further improve the reliability of the temperature measurement system 81.

### Second Embodiment

A second embodiment of a temperature measurement system according to the present invention and a manufacturing method of the temperature measurement system will be described with reference to the accompanying drawings.

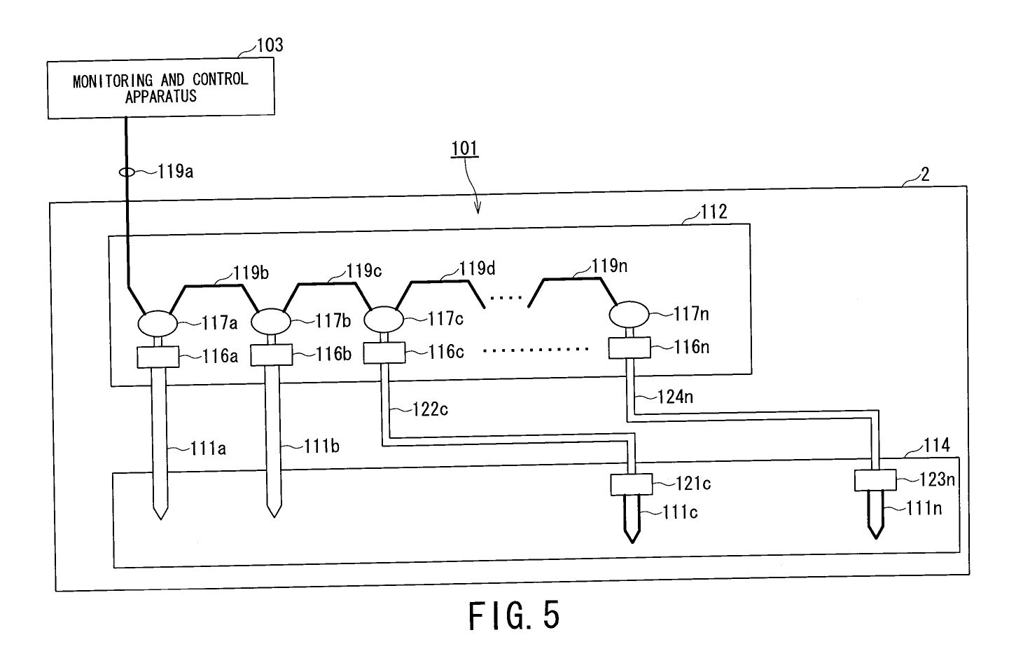

FIG. 5 is a view showing a configuration of a second embodiment of a temperature measurement system according to the present invention.

The configurations and portions corresponding to those of the temperature measurement system 1 according to the first embodiment are denoted by the same reference numerals and characters, and the description thereof is omitted.

A temperature measurement system 101 according to the second embodiment is different from the first embodiment in that a measurement area 114 measured by thermocouples is large, and n thermocouples (20 thermocouples (n=20) in the second embodiment) are housed in one housing 112. Here, “a large number” means, for example, a maximum number of thermocouples which can be connected by the Daisy chain system.

The temperature measurement system 101 is mainly provided in the industrial plant 2, and is connected to a monitoring and control apparatus 103 provided outside the industrial plant 2 by a transmission cable 119a.

Thermocouples 111a and 111b are provided as thermocouples for transmitting thermo-electromotive forces by a first system. The thermocouples 111a and 111b includes, at the cold junctions thereof, A/D converters 116a and 116b and adapters 117a and 117b, respectively. The A/D converters 116a and 116b (transmission signal conversion units) respectively A/D-convert the thermo-electromotive forces generated by the thermocouples 111a and 111b to transmission signals and output the transmission signals. The adapters 117a and 117b (transmission units) transmit the transmission signals transmitted from the A/D converters 116a and 116b to transmission cables 119a and 119b, respectively.

A thermocouple 111c is provided as a thermocouple for transmitting a thermo-electromotive force by a second system. The thermocouple 111c includes, at the cold junction thereof, a terminal box 121c, an A/D converter 116c, and an adapter 117c in this order. The terminal box 121c is connected to the A/D converter 116c by a compensation lead wire 122c.

The terminal box 121c (relaying apparatus) connects the thermocouple 111c to the compensation lead wire 122c. The terminal box 121c supplies the thermo-electromotive force (small thermo-electromotive force) generated by the thermocouple 111c to the compensation lead wire 122c (third connection unit). The A/D converter 116c (transmission signal conversion unit) A/D-converts the thermo-electromotive force transmitted via the compensation lead wire 122c to a transmission signal and outputs the transmission signal. The adapter 117c (transmission unit) transmits the transmission signal transmitted from the A/D converter 116c to a transmission cable 119c.

A thermocouple 111n is provided as a thermocouple for transmitting a thermo-electromotive force by a third system. The thermocouple 111n includes, at the cold junction thereof, a converter 123n, an A/D converter 116n, and an adapter 117n in this order. The converter 123n is connected to the A/D converter 116n by a hard cable 124n.

The converter 123n (current signal conversion unit) converts the thermo-electromotive force (small thermo-electromotive force) generated by the thermocouple 111n to a current signal of 4 to 20 mA (or a voltage signal of 1 to 5 V) and outputs the signal. The current signal (voltage signal) is transmitted to the A/D converter 116n via the hard cable 124n (third connection unit). The hard cable 124n has required rigidity and/or elasticity. The A/D converter 116n (transmission signal conversion unit) A/D-converts the transmitted thermo-electromotive forces to a transmission signal and outputs the transmission signal. The adapter 117n (transmission unit) transmits the transmission signal transmitted from the A/D converter 116n to a transmission cable 119n.

Note that the cost of the compensation lead wire 122c is less than the cost of the thermocouple of the same length. For this reason, in the case where the distance between the housing 112 and the hot junctions (measurement area 114) of the thermocouples 111a to 111d is large, the facility cost can be reduced more when the cold junction of the thermocouple 111c is connected to the A/D converter 116c by the second system via the compensation lead wire 122c, than when the cold junctions of thermocouples 111a and 111b are respectively connected to the A/D converters 116a and 116b by the first system.

Further, the cost of the hard cable 124n is less than the cost of the compensation lead wire 122c of the same length. Therefore, from the same reason described above, the facility cost can be reduced more when the third system is adopted than when the second system is adopted.

The second and third systems are effective in the case where the distance between the hot junction (measurement area 114) and the housing 112 is large (for example, from about 10 m to 30 m), for example, where the distance is large to an extent that it is not realistic to house the cold junctions of the thermocouples 111c and 111n in the housing 112.

The transmission cables 119a to 119n are, for example, optical cables, and transmit the transmission signals transmitted from the adapters 117a to 117n to the monitoring and control apparatus 103. The transmission cables 119b to 119n (first connection unit) connect the mutually adjacent adapters 117a to 117n. The transmission signals transmitted from the respective adapters 117b to 117n are transmitted to the adapters 117a to 117 (n−1) successively through the required transmission cables 119b to 119n, and are finally transmitted to the monitoring and control apparatus 103 via the transmission cable 119a (second connection unit). The transmission cables 119a to 119n are connected by a wiring system (so-called Daisy Chain system) in which the mutually adjacent adapters 117a to 117n are connected by the transmission cables 119a to 119n in series.

The housing 112 (housing unit) houses the transmission cables 119a to 119n (a part of the transmission cable 119a), the A/D converters 116a to 116n, the adapters 117a to 117n, the cold junctions at which the thermocouples 111a and 111b are respectively connected to the A/D converters 116a and 116b, and houses the compensation lead wire 122c and the hard cable 124n.

With the temperature measurement system 101 according to the second embodiment, the same effects as those of the first embodiment can be obtained even for a large number of the thermocouples 111a to 111n (20 thermocouples in the second embodiment).

That is, in the case where a large number of the thermocouples 111a to 111n are installed the distance between the housing 112 and a part of the thermocouples 111c to 111n becomes large. In this case, the thermocouples having long distance are required for housing the transmission cables in the housing 112, and the facility cost increases. However, when the thermocouples 111c to 111n connect to the compensation lead wire 122c and the hard cable 124n, and the thermo-electromotive forces of the thermocouples 111c to 111n are transmitted by using the compensation lead wire 122c and the hard cable 124n, the transmission cables 119a to 119n can be housed in the housing 112 without increase of the facility cost depending on the distance between the housing 112 and the thermocouples 111c to 111n.

Therefore, in the temperature measurement system 101, even when a large number of the thermocouples 111a to 111n are provided, the transmission cables 119a to 119n can be collectively housed in the housing 112 irrespective of the number of the thermocouples. Particularly when a large number of the thermocouples 111a to 111n are provided, it is possible to significantly reduce the facility costs and the installation work of the conduit pipes for protecting the transmission cables 119b to 119n.

Further, some parts of the compensation lead wire 122c and of the hard cable 124n are installed through the measurement area 114 which is the apparatus installation site area. However, the installation routes of the part of the compensation lead wire 122c and the part of the hard cable 124n are limited only in very short sections which are located at the cold junctions of the thermocouples 111a to 111n and at the surroundings of the cold junctions. Thus, the labor of the installation design work and of the installation work of the part of the compensation lead wire 122c and the part of the hard cable 124n is small. Further, in the place away from the measurement area 114, the installation routes of the compensation lead wire 122c and the hard cable 124n can be selected in the area (outside the apparatus installation site area) where the surrounding environment is organized, and hence the installation design work and the installation work can be easily performed.

Note that in the above, the example, in which 20 thermocouples are provided, is described, but the number of thermocouples housed in the one housing 112 is not limited to this. Further, in a large-scale industrial plant in which a large number of thermocouples 111a to 111n are installed, a plurality of housings 112 are provided so that a predetermined number of thermocouples 111a to 111n are housed in each of the housings 112.

### Third Embodiment

A third embodiment of a temperature measurement system according to the present invention and a manufacturing method of the temperature measurement system will be described with reference to the accompanying drawings.

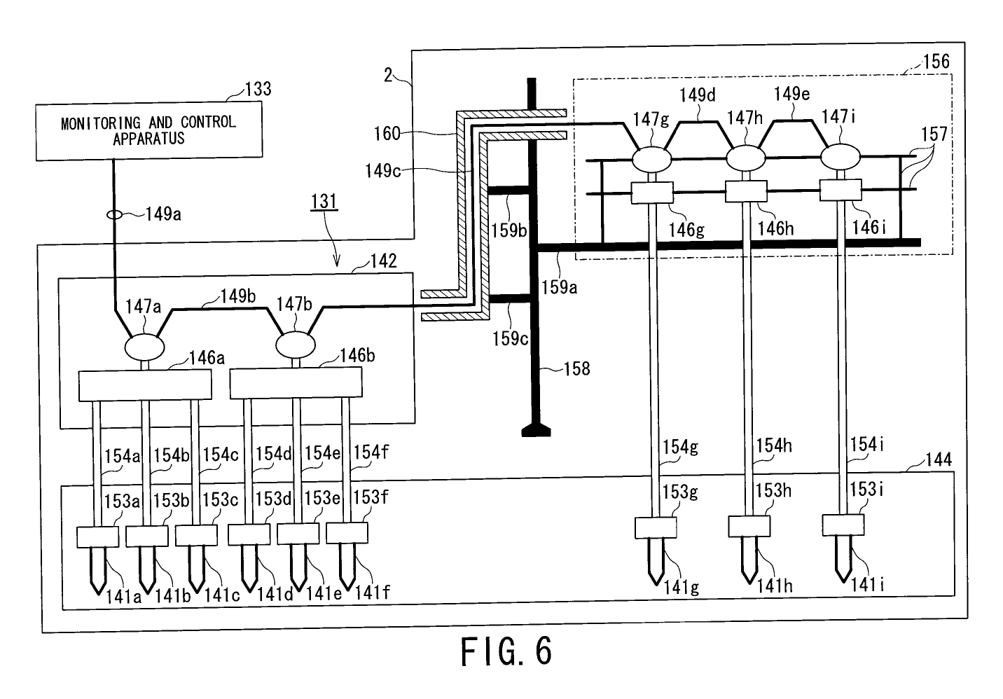

FIG. 6 is a view showing a configuration of a third embodiment of a temperature measurement system according to the present invention.

The configurations and portions corresponding to those of the temperature measurement systems 1 and 101 according to the first and second embodiments are denoted by the same reference numerals and characters, and the description thereof is omitted.

First, a problem, which can be considered about the temperature measurement systems according to the first and second embodiments, is described.

In the case where a detailed plan, including an apparatus arrangement and a building structure and also including a measurement area (apparatus installation site area), is created at the time of initial planning of an industrial plant, the installation place of the housing is also planned in an initial stage so that the installation place can also be secured.

In practice, however, after the planning and arrangement of main facility apparatuses are performed, the installation place of the housing is determined while the relations between the housing and the surrounding facility apparatuses are adjusted. For this reason, there is a high possibility of occurrence of the case where there is no installation place of the housing.

In such case, when, instead of being installed, for example, on the floor surface, the housing is attached to, for example, a building structure (for example, a wall, a pillar, a beam, and a ceiling surface) of the industrial plant, the three-dimensional height can also be used for the installation of the housing.

When a wall or a pillar, to which the housing is attached, can be determined in an initial stage of construction of the industrial plant, the structure, such as the pillar, can also be designed in consideration of the load of the housing. However, the installation place of the housing is not determined in the initial stage of construction of the industrial plant as described above, and hence the weight of the facilities installed at high places needs to be reduced.

Thus, in a temperature measurement system according to a third embodiment, transmission cables, and the like, are installed at high places by using a frame (a framed construction, rack), whereby the transmission cables are separated from the apparatus installation site area in which the facility apparatuses are intensively arranged, and thereby the influences of the surrounding environment, such as the influence of hot water, steam, or gas, and the influence of the human activities can be reduced.

In the following, a temperature measurement system 131 according to the third embodiment will be specifically described.

The temperature measurement system 131 is mainly provided in the industrial plant 2, and is connected to a monitoring and control apparatus 133 provided outside the industrial plant 2 by a transmission cable 149a (second connection unit).

Each of thermocouples 141a to 141f includes, at the cold junction thereof, each of terminal boxes 153a to 153f, one of A/D converters 146a and 146b, and one of adapters 147a and 147b in this order. Each of the terminal boxes 153a to 153f is connected to one of the A/D converters 146a and 146b by each of compensation lead wires 154a to 154f.

Each of the terminal boxes 153a to 153f is a relay unit and transmits the thermo-electromotive force (small thermo-electromotive force) generated by each of the thermocouples 141a to 141f to one of the A/D converters 146a and 146b via each of the compensation lead wires 154a to 154f. The A/D converters 146a and 146b (transmission signal conversion units) respectively A/D-convert the transmitted thermo-electromotive forces to transmission signals and output the transmission signals. The adapters 147a and 147b (transmission units) transmit the transmission signals transmitted from the A/D converters 146a and 146b to the transmission cables 149a and 149b, respectively. The A/D converter 146a and the adapter 147a are provided in common to the compensation lead wires 154a to 154c. The A/D converter 146b and the adapter 147b are provided in common to the compensation lead wires 154d to 154f.

A housing 142 (housing unit) houses the transmission cable 149b (parts of transmission cables 149a and 149c), the A/D converters 146a and 146b, the adapters 147a and 147b, and the compensation lead wires 154a to 154f each of which connects each of the thermocouples 141a to 141f to one of the A/D converters 146a and 146b. The housing 142 is installed, for example on the floor surface of the industrial plant 2.

Thermocouples 141g to 141i respectively include, at cold junctions thereof, terminal boxes 153g to 153i, A/D converters 146g to 146i, and adapters 147g to 147i in this order. The terminal boxes 153g to 153i are respectively connected to the A/D converters 146g to 146i by the compensation lead wires 154g to 154i.

The terminal boxes 153g to 153i are relay units and respectively transmit the thermo-electromotive forces (small thermo-electromotive forces) generated by the thermocouples 141g to 141i to the A/D converters 146g to 146i via the compensation lead wires 154g to 154i. The A/D converters 146g to 146i (transmission signal conversion units) respectively A/D-convert the transmitted thermo-electromotive forces to transmission signals, and output the transmission signals. The adapters 147g to 147i (transmission units) respectively transmit the transmission signals transmitted from the A/D converters 146g to 146i to the transmission cables 149c to 149e (first connection units).

Note that, in place of the terminal boxes 153a to 153i and of the compensation lead wires 154a to 154i, the thermocouples 141a to 141i may respectively include the converters and the hard cables (see the second embodiment).

Each of the A/D converters 146g to 146i and of the adapters 147g to 147i is housed in a frame (a framed construction, rack) 156 by being fixed to a support pipe 157 by a fixing unit, such as a clamp.

The frame 156 (housing unit) is supported at a predetermined height by a building structure of the industrial plant 2. In FIG. 6, the frame 156 is supported by a support 159a horizontally extended from a pillar 158 which is a building structure of the industrial plant 2. The frame 156 is not a closed type box, such as the housing 142, but an open-type rack formed by combining the support pipes 157 made of, for example, a metal or FRP.

The transmission cable 149c connected to the adapter 147g is connected to the adapter 147b housed in the housing 142. The transmission cable 149c is connected to the adapter 147b through places where the influence of the surrounding environment, such as the influence of hot water, steam, or gas, and the influence of human activities cannot be neglected. For this reason, the transmission cable 149c is made to pass through the inside of a conduit pipe 160 and is protected by the conduit pipe 160. The conduit pipe 160 is supported by supports 159b and 159c and is provided in the vertical direction along the pillar 158.

The frame 156 is installed in an area which is separated from the apparatus installation site area as the measurement area 144 and in which the influence of the surrounding environment, such as the influence of hot water, steam, or gas, and the influence of human activities can be neglected. For this reason, the transmission cables 149c to 149e connected to the adapters 147g to 147i need not be housed and protected in a closed space, such as the space in the housing 142.

That is, with the temperature measurement system 131 according to the third embodiment, it is possible to reduce the weight of the facilities for protecting the transmission cables 149a to 149e, and to reduce the facility cost.

Although several embodiments of the present invention have been described above, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A temperature measurement system comprising:
a plurality of thermocouples;
a transmission signal conversion unit configured to convert, to a transmission signal, the thermo-electromotive force generated by each of the plurality of the thermocouple and configured to output the transmission signal;
a plurality of transmission units configured to transmit the transmission signal outputted from the transmission signal conversion unit;
a first connection unit configured to connect between each of the plurality of the transmission units;
a second connection unit configured to connect at least one of the plurality of transmission units to a processing unit configured to process the transmission signal; and
a housing unit configured to house at least the first connection unit.

2. The temperature measurement system according to claim 1, wherein the housing unit is a housing has a self-closing property.

3. The temperature measurement system according to claim 2, wherein
the first connection unit connects between each of the plurality of the transmission units in series, and
each of the plurality of the transmission units transmits the transmission signal via the first connection unit so as to allow the transmission signal to be transmitted to the processing unit via the second connection unit.

4. The temperature measurement system according to claim 3, wherein
the housing unit further houses the transmission signal conversion unit and the plurality of transmission units, and
each of the plurality of the thermocouples is connected to the transmission signal conversion unit in the housing unit.

5. The temperature measurement system according to claim 1, further comprising:
a relay unit connected to each of the plurality of the thermocouples; and
a third connection unit configured to connect the relay unit to the transmission signal conversion unit.

6. The temperature measurement system according to claim 5, wherein
the third connection unit is a compensation lead wire, and
the relay unit is a relay apparatus configured to supply the thermo-electromotive force to the compensation lead wire.

7. The temperature measurement system according to claim 5, wherein
the relay unit is a current signal conversion unit configured to convert the thermo-electromotive force generated by each of the plurality of the thermocouples to a current signal or a voltage signal, and
the third connection unit is a cable configured to transmit the current signal or the voltage signal to the transmission signal conversion unit.

8. The temperature measurement system according to claim 1, wherein two or more of the second connection units are provided.

9. The temperature measurement system according to claim 1, wherein the housing unit is a frame supported by a building structure in which the temperature measurement system is provided.

10. A manufacturing method of a temperature measurement system, the manufacturing method comprising:
installing a plurality of thermocouples in a measurement area;
connecting, to each of the plurality of the thermocouples, a transmission signal conversion unit that is configured to convert the thermo-electromotive force generated by each of the plurality of the thermocouple to a transmission signal and is configured to output the transmission signal;
connecting, to the transmission signal conversion unit, a plurality of a transmission units configured to transmit the transmission signal outputted from the transmission signal conversion unit;
connecting between each of the plurality of the transmission units by a first connection unit;
connecting, by a second connection unit, at least one of the plurality of the transmission units to a processing unit configured to process the transmission signal; and
housing at least the first connection unit in a housing unit.
